(19) United States
(12) Patent Application Publication
(10) Pub. No.: US 2019/0228821 A1
(43) Pub. Date: Jul. 25, 2019

(54) Programmable High-Speed and Low-power Mode FPGA Memory with Configurable Floating Bitlines Scheme

(71) Applicant: Intel Corporation, Santa Clara, CA (US)

(72) Inventors: Wei Yee Koay, Penang (MY); Rajiv Kumar, Penang (MY); Pek Mui Goh, Penang (MY); Kuan Cheng Tang, Penang (MY); Wei Chieh Wong, Kedah (MY)

(73) Assignee: Intel Corporation, Santa Clara, CA (US)

(21) Appl. No.: 16/370,028

(22) Filed: Mar. 29, 2019

(51) Int. Cl. G11C 11/419; H03K 19/177; G11C 11/418; G11C 11/412

(52) U.S. Cl. CPC G11C 11/419; H03K 19/1776; H03K 19/20; G11C 11/412; G11C 11/418

(57) ABSTRACT

A method for operating an SRAM of an FPGA in a high or low-power mode includes a CRAM of the FPGA storing control bits for controlling whether pages of the SRAM operate in the high or low-power mode. A control circuit of the FPGA uses the control bits, a system clock signal, and address for the pages to determine whether to operate the pages in the high or low-power mode and to control the timing for precharging and tristating read bitlines of the pages for the high and low-power modes. In the high-power mode the read bitlines are precharged longer than in the low-power mode, and in the high-power mode the read bitlines are tristated less than in the low-power mode. Precharging the read bitlines for a lesser time in the low-power mode reduces DC leakage current in the lower power mode compared to the high-power mode.

### FIELD OF THE DISCLOSURE

The present disclosure relates to a power control circuit for a configurable integrated circuit die. More specifically, the present disclosure relates to a power control circuit for a configurable integrated circuit die that controls line precharge and line float for power consumption reduction.

### BACKGROUND OF THE INVENTION

Configurable integrated circuit dies are configurable to implement a variety of circuit devices. The different circuit devices may have different performance and power requirements. The embedded memory blocks of a configurable integrated circuit die are designed to support the different performance and power requirements of the circuit devices. Bitline precharge facilitates high-speed operation of the embedded memory blocks and circuit devices. Bitline precharge also incurs leakage current. Leakage current from embedded memory blocks across a large portion of a configurable integrated circuit die may amount to a relatively large amount of current and power consumed by the die. Relatively large leakage current that results from bitline precharge across a large portion the embedded memory of a configurable integrated circuit die is not desirable for a variety of circuit devices configured into configurable integrated circuit dies.

Thus, an impetus exists to reduce leakage current across a configurable integrated circuit dies from the embedded memory due to the precharge of the bitlines of the embedded memory.

### BRIEF DESCRIPTION OF THE DRAWINGS

FIG. 1 illustrates a configurable integrated circuit (IC) die, in an embodiment.

FIG. 2 illustrates a logic element that may be included in one of the logic array blocks of a configurable IC die.

FIG. 3 illustrates a memory cell, such as an SRAM cell of an SRAM of a configurable IC die.

FIG. 4 illustrates an SRAM array of a configurable IC die, in an embodiment.

FIG. 5 illustrates an SRAM array of a configurable IC die, in an embodiment.

FIG. 6 illustrates a control circuit for one or more read bitline of a memory device of a configurable IC die, in an implementation.

FIGS. 7 and 8 are flow diagram of a method for a high-speed mode of operation of a memory cell of a page of memory cells and a timing diagram for a high-speed mode of operation during a read cycle of the memory cell.

FIGS. 9 and 10 are a flow diagram of a method for a low-power mode of operation of a memory cell of a page of memory cells and a timing diagram for a low-power mode of operation during a read cycle of the memory cell.

FIG. 11 shows the memory device where one page of the memory device is operated in the low-power mode of operation.

FIG. 12 shows a diagram of a high-speed read cycle and a low-power read cycle.

FIG. 13 is a flow diagram for determining whether an instance of memory should be configured for the low-power mode of operation or the high-speed mode of operation based on the timing performance of a read cycle.

FIG. 14 illustrates a data system, in an embodiment.

FIG. 15 illustrates a data system, in an embodiment.

### DETAILED DESCRIPTION

Configurable integrated circuit (IC) dies that are often packaged discretely and as system-in-package (SiP) devices continue to fuel development in IC markets. Circuit emulation markets, ASIC prototyping markets, and data center markets are a few of the developing IC markets fueled by configurable IC dies. Configurable IC dies directed toward circuit emulation markets often include several configurable IC dies packaged as a SiP to facilitate an almost unlimited number of emulated circuits where a single configurable IC die may be unable to supply sufficient programmable fabric for implementing an emulation circuit. Configurable IC dies directed toward ASIC prototyping markets often include a number of configurable ICs dies packaged as a SiP to implement a variety of ASICs. Configurable IC dies directed toward data center markets are often discretely packaged or packaged as SiPs to facilitate ASIC functions in the data center, acceleration in the data center, to add processing capability, to add network and virtual network capability, to add non-volatile memory express capability, or other capabilities.

Configurable IC dies directed toward these markets and other markets may include field programmable gate arrays (FPGAs), programmable logic devices (PLDs), complex programmable logic devices (CPLDs), programmable logic arrays (PLAs), configurable logic arrays (CLAs), memory, transfer dies, and other ICs. Configurable IC dies typically include a number of configurable logic blocks that may be configured to implement various circuits. The logic blocks are interconnected by configurable interconnect structures that may be configured to interconnect the logic blocks in almost any desired configuration to provide almost any desired circuit.

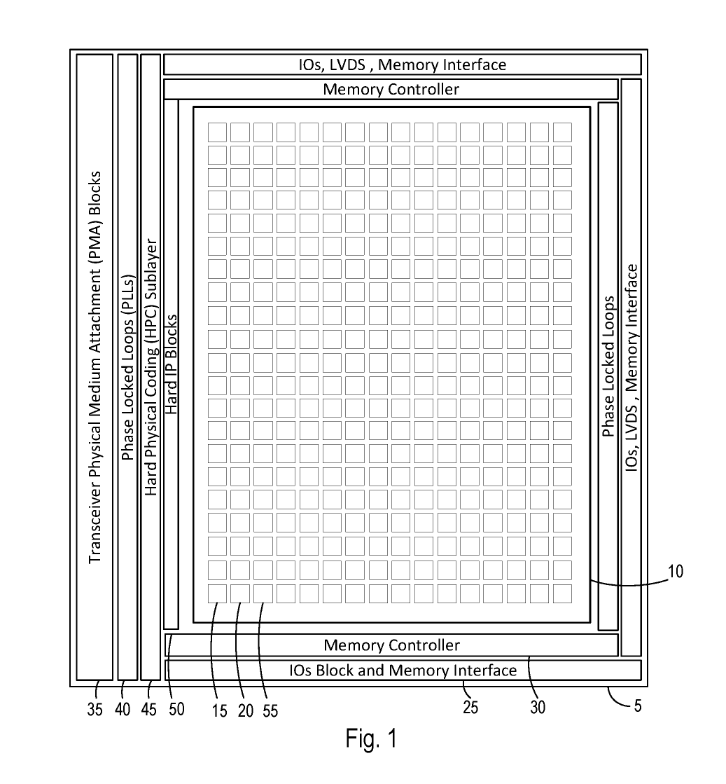

FIG. 1 illustrates a configurable integrated circuit (IC) die 5, in an embodiment. The configurable IC die 5 includes a core fabric 10 and a periphery portion of hardened circuits. The hardened circuits may include an input-output (IO) block and memory interface 25, a memory controller 30, a transceiver physical medium attachment (PMA) block 35, one or more phased locked loop blocks 40, a hard physical coding (HPC) sublayer 45, and one or more hard intellectual property (IC) blocks 50. The configurable IC die may include one or more of these hardened circuits in any combination.

The core fabric may include a number of columns 15 of logic array blocks, one or more columns 20 of configurable random access memories (CRAMs), and one or more columns 55 of random access memory blocks. The core fabric may include circuit devices, such as one or more columns of digital signal processors.

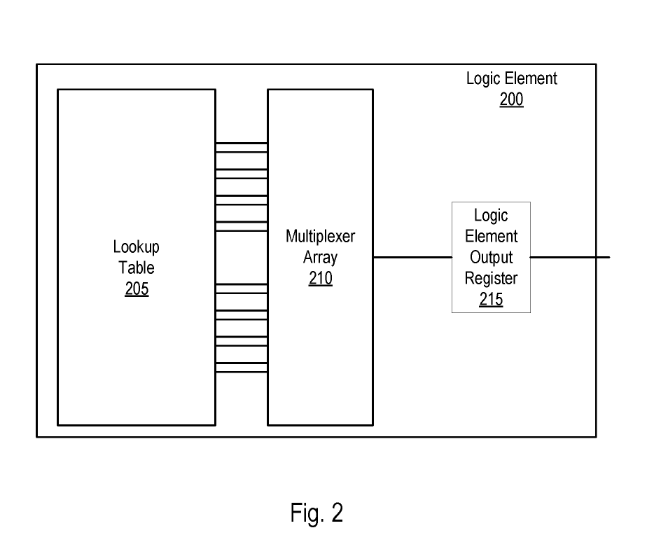

FIG. 2 illustrates a logic element 200 that may be included in one of the logic array blocks. The logic element may include a lookup table 205, a multiplexer array 210, and an output element 215. The lookup table may include a static random access memory (SRAM) array that is connected to the multiplexer array. The multiplexer array may be connected to the output element and may be positioned between the lookup table and the IO element. The IO element may include a register for registered output, a combinatorial output, or both. The SRAM array and multiplexer array may implement a number of combinatorial logic functions where a result of a combinatorial logic function may be output from the logic element by the IO element.

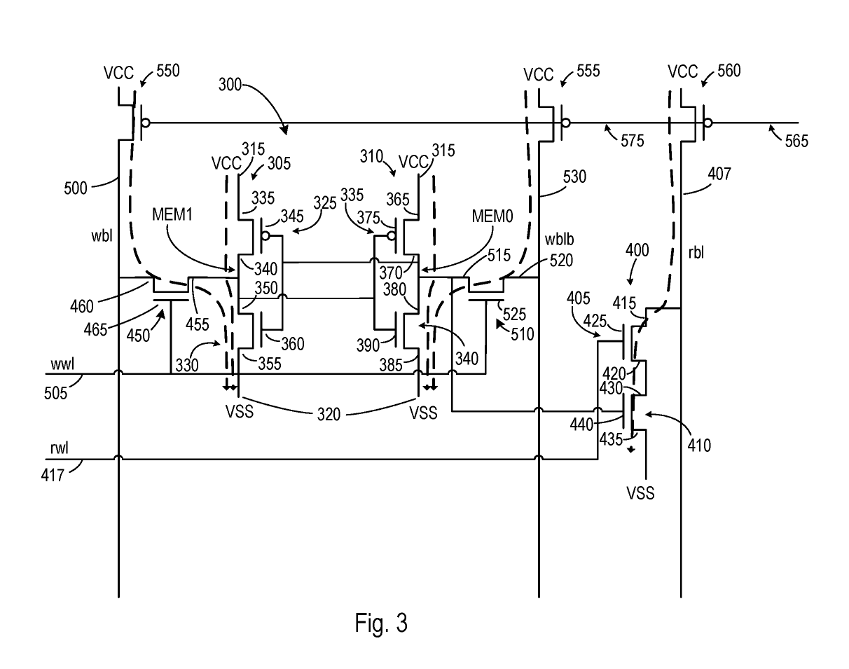

FIG. 3 illustrates a memory cell 300, such as an SRAM cell. Memory cell 300 may be a memory cell that is included in one of memory blocks 55 shown in FIG. 1, which may be a memory block of a lookup table or other memory of the core fabric. The memory cell includes a first inverter 305 and a second inverter 310. The first and second inverters are cross-connected and are configured in parallel between a power supply line 315 (e.g., a power supply line on which positive power supply voltage Vcc is provided) and a ground line 320 (e.g., a ground line on which a ground VSS is provided).

The first inverter includes a first transistor 325 and a second transistor 330. The second inverter includes a third transistor 335 and a fourth transistor 340. The first and third transistors may be the same type of transistors, such as p-channel transistors, and the second and fourth transistors may be the same type of transistors, such as n-channel transistors.

The first transistor 325 includes a first node 335 (e.g., a first source-drain node), a second node 340 (e.g., a second source-drain node), and a third node 345 (e.g., a gate node). The second transistor 330 includes a first node 350 (e.g., a first source-drain node), a second node 355 (e.g., a second source-drain node), and a third node 360 (e.g., a gate node).

First node 335 of the first transistor 325 is connected to the power supply line. The second node 340 of the first transistor 325 is connected to the first node 350 of the second transistor 330. The connected nodes 340 and 350 are a first memory node 1 (MEM1) of the memory cell. The second node 355 of the second transistor 330 is connected to the ground line. In the described configuration, the first transistor 325 is sometimes referred to as a pull-up transistor and the second transistor 330 is sometimes referred to as a pull-down transistor.

The third transistor 335 includes a first node 365 (e.g., a first source-drain node), a second node 370 (e.g., a second source-drain node), and a third node 375 (e.g., a gate node). The fourth transistor 340 includes a first node 380 (e.g., a first source-drain node), a second node 385 (e.g., a second source-drain node), and a third node 390 (e.g., a gate node).

First node 365 of the third transistor 335 is connected to the power supply line. The second node 370 of the third transistor 335 is connected to the first node 380 of the fourth transistor 340. The connected nodes 370 and 300 are a second memory node 0 (MEM0) of the memory cell. The second node 385 of the fourth transistor 340 is connected to the ground line. In the described configuration, the third transistor 335 is sometimes referred to as a pull-up transistor and the fourth transistor 340 is sometimes referred to as a pull-down transistor.

The third node 345 (e.g., gate) of the first transistor 325 and the sixth node 360 (e.g., gate) of the second transistor 330 may be connected and these nodes may be connected to the second memory node 0. The third node 375 (e.g., gate) of the third transistor 335 and the sixth node 390 (e.g., gate) of the fourth transistor 340 may be connected and these nodes may be connected to the first memory node 1.

The memory cell includes read-access circuit 400. Read-access circuit 400 includes a first transistor 405 (e.g., a pull-down transistor) and a second transistor 410 (e.g., a pull-down transistor). The first and second transistors may both be n-channel transistors. The first transistor includes a first node 415 (e.g., a first source-drain node), a second node 420 (e.g., a second source-drain node), and a third node 425 (e.g., a gate node). The second transistor 410 includes a first node 430 (e.g., a first source-drain node), a second node 435 (e.g., a second source-drain node), and a third node 440 (e.g., a gate node).

First node 415 of the first transistor 405 is connected to a read bitline 407. The second node 420 of the first transistor 405 is connected to the first node 380 of the second transistor 410. The second node 485 of the second transistor 410 is connected to the ground line.

The third node 425 of the first transistor 405 is connected to a read wordline 417 (rw1). The third node 440 of the second transistor 410 is connected to the second memory node 0.

The first memory node 1 (MEM1) is connected to a first enable transistor 450. The first enable transistor may be an n-channel transistor. The first enable transistor includes a first node 455 (e.g., a first source-drain node), a second node 460 (e.g., a second source-drain node), and a third node 465 (e.g., a gate node). The first node 455 of the first enable transistor is connected to the first memory node 1, the second node 460 of the first enable transistor is connected to a write bitline 500 (wb1), and the third node 450 of the first enable transistor is connected to a write wordline 505 (ww1).

The second memory node 0 (MEM0) is connected to a second enable transistor 510. The second enable transistor may be an n-channel transistor. The second enable transistor includes a first node 515 (e.g., a first source-drain node), a second node 520 (e.g., a second source-drain node), and a third node 525 (e.g., a gate node). The first node 515 of the second enable transistor is connected to the second memory node 0, the second node 520 of the second enable transistor is connected to a write bitline bar 530 (wblb), and the third node 525 of the second enable transistor is connected to the write wordline 505.

The first and second memory nodes store the memory bits for the SRAM cell. The first and second memory nodes may be written to when the first enable transistor 450, the second enable transistor 510, or both are on and transfer the states on the write bit line, write bitline bar, or both to the memory nodes. The second memory node of the SRAM cell may be read when the first transistor 405 and the second transistor 410 of the read enable circuit 400 are on. Sense amp circuitry for amplifying the charge state of the read bitline is described below.

The write bitline 500, the write bitline bar 530, and the read bitline 407 are respectively coupled to precharge transistors 550, 555, and 560. The precharge transistors may be p-channel transistors. The precharge transistors are adapted to be turned on based on a precharge signal applied to the precharge transistors from a precharge line 565 and 575. When the precharge transistors are turned on 550 and 555 are turned on, write bitline 500 and write bitline bar 530 are precharged. When precharge transistor 560 is turned on, the read bitline 407 is precharged, which facilitates relatively high-speed reading of the first memory node 1, the second memory node 0, or both.

When the write bitline 500, the write bitline bar 530, and the read bitline 407 are precharged, current leakage in the SRAM cell increases compared to when these bitlines are not precharged. Specifically, the current leakage across the first and second inverters 305 and 310, the read-access circuit 400, and the first and second enable transistors 450 and 510 increases compared to when the bitlines are not precharged. The dashed line shown in FIG. 3 indicates the current leakage paths.

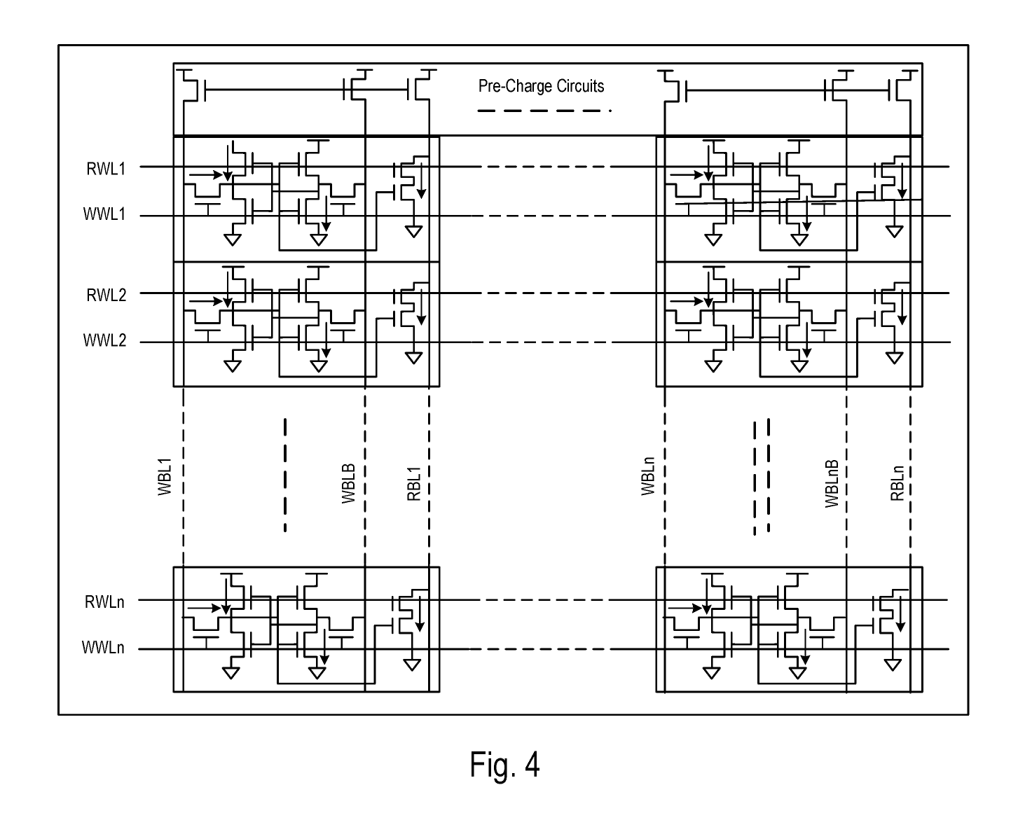

FIG. 4 illustrates an SRAM array. Various write bitlines, write bitline bars, and the read bitlines may be precharged and the current leakage in the SRAM cell increases compared to when the bitlines are not precharged. When all of the read bitlines are precharged prior to and after evaluation of the SRAM cells, the leakage current from the SRAM array is greater than when the bitlines are not precharged. The arrows in FIG. 4 across the various transistors in the SRAM array indicate the current leakage paths.

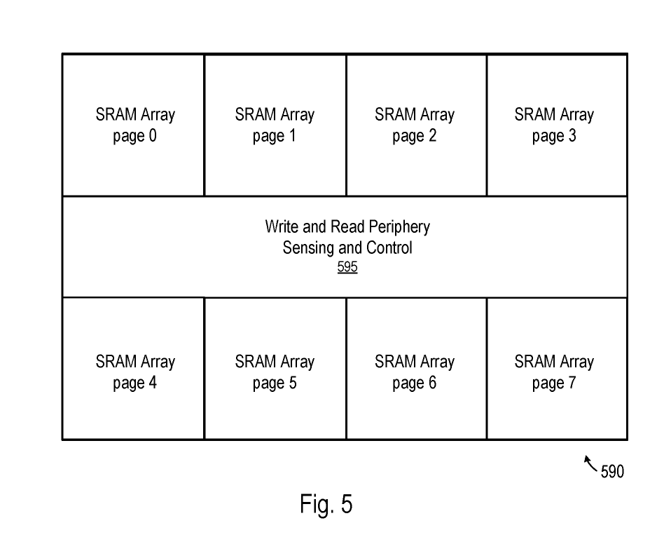

FIG. 5 illustrates an SRAM array 590, in an embodiment. The SRAM array includes write and read periphery sensing and control circuity 595 and includes a number of pages of memory cells. In the example embodiment, the SRAM array includes 8 pages of SRAM memory cells. The pages are labeled page 0, page 1, page 2, page 3, page 4, page 5, page 6, and page 7. Other embodiments may include more or fewer number of pages of memory cells. In an embodiment, power consumption of the pages of memory cells are controllable on a per page basis.

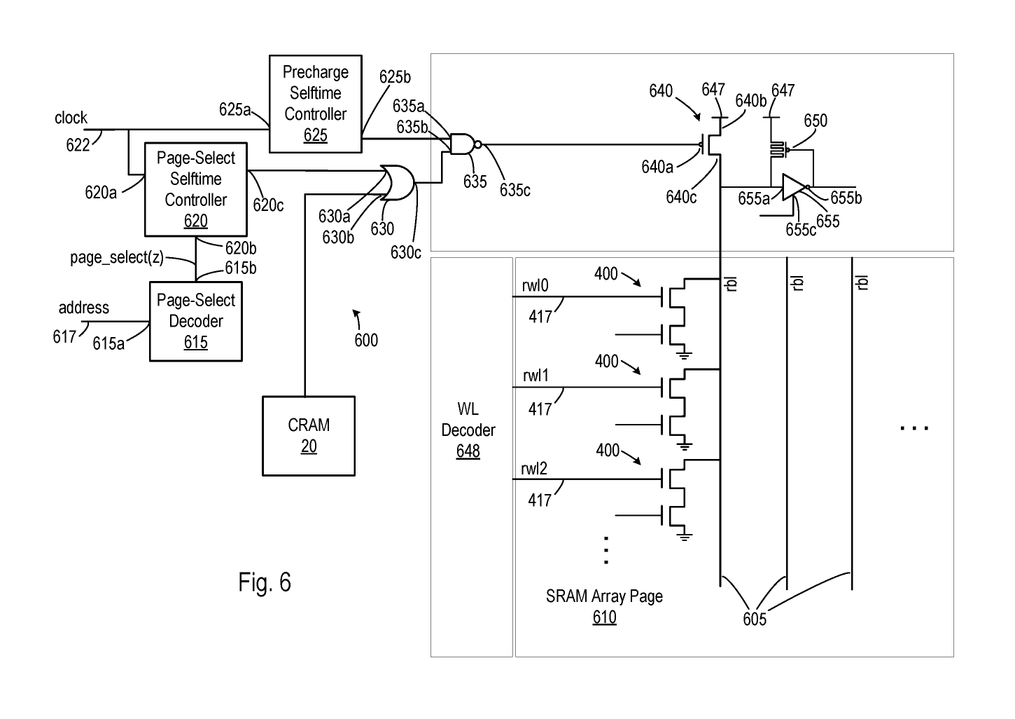

FIG. 6 illustrates a control circuit 600 for one or more read bitline of a memory device, in an implementation. The control circuit may control the precharge of one or more read bitlines 605 of a page 610 of memory cells of a memory device, such as a page of SRAM cells of an SRAM array.

Control circuit 600 includes a page-select decoder 615, a page-select selftime controller 620, a precharged selftime controller 625, a first logic gate 630, and a second logic gate 635. Control circuit 600 is connected to one or more transistors 640 of page 610 of memory cells. Transistor 640 may be a pull-up transistor that is adapted to pull-up (i.e., precharge) one or more read bitlines 605 of the page of memory cells. Control circuit 600 is adapted to control the timing for turning on and off transistor 640 to thereby control the timing for precharging one or more of the read bitlines.

The page-select decoder 615 includes an input 615a and an output 615b. Input 615a is connected to an address supply line 617 and is adapted to receive an address for one or more memory cells of the page of memory cells.

Page-select selftime controller 620 includes a first input 620a, a second input 620b, and an output 620c. First input 620a is connected to a clock supply line 622 and is adapted to receive a clock signal via the clock supply line. The clock supply line may be connected to any node of a clock tree of the configurable IC die. Second input 620b is connected to the output 615b of the page-select decoder 615.

The first logic gate 630 includes a first input 630a, a second input 630b, and an output 630c. The first logic gate may be an OR gate or another type of logic gate. The first input 630a is connected to the output 620c of the page-select selftime controller 620. The second input 630b is connected to an output of one of the CRAMs 20 that may be included in one of the rows of CRAMs located in the core fabric of the configurable IC die.

The precharge selftime controller 625 includes an input 625a and an output 625b. Input 625a is connected to clock supply line 622 and is adapted to receive the clock signal via the clock supply line. Input 625a of the precharge selftime controller 625 may be connected to the first input 620a of the page-select selftime controller 620.

The second logic gate 635 includes a first input 635a, a second input 635b, and an output 635c. The second logic gate may be a NAND gate or other type of logic gate. The first input 635a of the second logic gate 635 is connected to the output 625b of the precharge selftime controller 625. The second input 635b of the second logic gate 635 is connected to the output 630c of the first logic gate 630.

Transistor 640 of page 610 of the memory cells may include a first node (e.g., a control gate) 640a, a second node (e.g., a first source-drain node) 640b, and a third node (e.g., a second source-drain node) 640c. In an embodiment, transistor 640 is a p-channel transistor. Control gate 640a is connected to output 635c of the second logic gate 635. The first source-drain node 640b is connected to a power supply line 647 (e.g., a power supply line on which positive power supply voltage Vcc is provided). The second source-drain node 640c is connected to one or more of the read bitlines 605. Each read bitline 605 is connected to a number of read-access circuits 400. Each read-access circuit 400 is a read-access circuit for a memory cell. The memory cells and their associated read-access circuits are shown in FIG. 3 and described above. A word line decoder 648 is connected to the read word lines (e.g., rwl0, rwl1, rwl2 . . . rwln), which are connected to the read-access circuits. The connection of the read word lines and read-access circuits are shown in FIG. 3 above and are described above.

The read bitlines are respectively connected to the inputs of a number of sense amps of the page of memory cells. One sense amp 655 is shown in FIG. 6 connected to one of the read bitlines 605. The sense amp includes a sense amp input 655a, a sense amp output 655b, and a sense amp enable input 655c. A keeper transistor 650 may be connected between the sense amp input 655a and the sense amp output 655b. The control gate of the keeper transistor may be connected to the sense output 655b, a first source-drain node of the keeper transistor may be connected to a power supply line, and a second source-drain node of the keeper transistor may be coupled to the input of the sense amp. The keeper transistor is adapted to hold an input state (e.g., high input state or low input state) on the sense amp input 655a.

In an alternative embodiment, control circuit 600 includes complementary circuits compared to the circuits described above. For example, the first logic circuit may be a NOR gate, the second logic circuit may be an AND gate, transistor 640 may be a p-channel transistor, and the circuits composing the page-select decoder, the page-select selftime controller, and the prechared selftime controller may include circuits so that the circuits perform complementary functions compared to the function of these circuits described immediately below. The CRAM may output complimentary control bits compared to the control bits described immediately below.

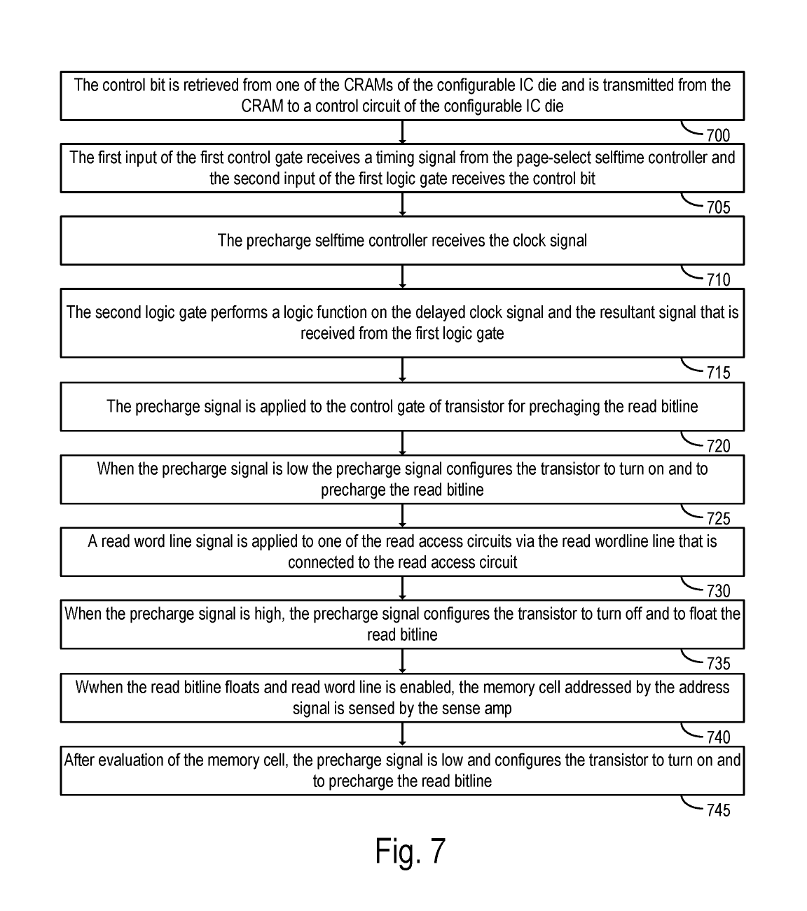

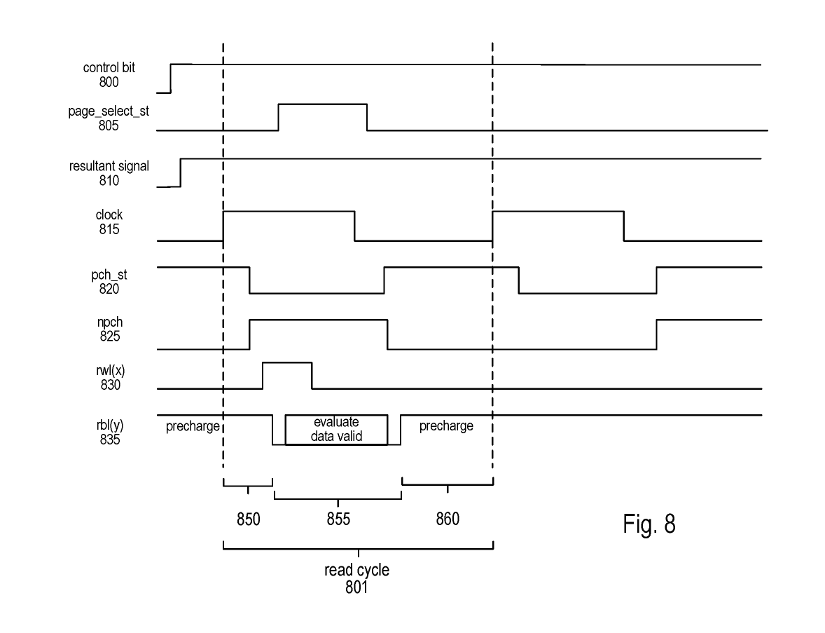

FIGS. 7 and 8 are a flow diagram of a method for a high-speed mode of operation of a memory cell of a page of memory cells and a timing diagram for the high-speed mode of operation during a read cycle 801 of the memory cell. FIGS. 7 and 8 are described together. The flow diagram represents one example embodiment. Steps may be added to, removed from, or combined in the flow diagram without deviating from the scope of the embodiment.

At 700, a control bit 800 is retrieved from a CRAM 20 of configurable IC die 5 and is transmitted from the CRAM to the control circuit 600. Specifically, the control bit is transmitted to the second input 630b of the first logic gate 630.

For the high-speed mode of operation, the control bit has the same state for all of the pages of memory cells of a memory device so that all of the pages of the memory device operate in a high-speed mode of operation. That is all control circuits 600 of every page of a memory device uses the control bit for configuring the pages of memory cells for high-power operation. The following describes the use of the control bit by one of the control circuits of a page to operate one read bitline of the page in a high-speed mode of operation. The described method of operation of the read bitline in the high-speed mode of operation is the same method of operation for all read bitlines for all pages of a memory in the high-power mode of operation.

In one embodiment, the control bit may be high for all pages and in an alternative embodiment, the control bit is low for all pages. In the example embodiment described below, the control bit is high for the high-speed mode of operation.

The memory device may be a lookup table 205 of a logic element 200 of configurable IC die 5 or may be another memory device of the configurable IC die. The memory device may be an SRAM of the configurable IC die. The CRAM may retrieve the control bit based on receipt of the memory address by the CRAM. In an embodiment, the CRAM retrieves the control bit based on the receipt of a memory address for the memory device that is received by the CRAM.

At 705, the first input 630a of the first logic gate 630 receives a timing signal 805 from the page-select selftime controller 620 and the second input 630b of the first logic gate 630 receives the control bit 800. Timing signal 805 is sometimes referred to as the page-select selftime signal (i.e., page_select_st). The first logic gate performs a first logic operation (e.g., an OR operation) on the received signals and outputs a resultant signal 810 of the first logic operation on output 630c. The resultant signal 810 of the logic operation is transmitted from output 630c to the second input 635b of the second logic gate 635.

In an embodiment where the first logic gate is an OR gate and the control bit received from the CRAM is high, the resultant signal 810 output from the OR gate is high. That is, the timing signal 805 received at the first input 630a from the page-select selftime controller does not control the output of the first logic gate when the control bit is high. Stated alternatively, the page-select selftime controller 620 and the page-select decoder 615 are bypassed in the high-speed mode of operation. Therefore, the shape of timing signal 805 is not presently described but is described further below with respect to the low-power mode of operation of the page of memory cells.

At 710, the precharge selftime controller 625 receives a clock signal 815 at the input 625a of the controller. The controller delays the clock signal and transmits the delayed clock signal 820 to the first input 635a of the second logic gate 635. Delayed clock signal 820 is sometimes referred to as the precharge selftime signal (i.e., pch_st).

At 715, the second logic gate 635 (e.g., a NAND gate) performs a second logic operation (e.g., a NAND operation) on the delayed clock signal 820 and the resultant signal 810 (e.g., high) that is received from the first logic gate. The result signal of the second logic operation is a precharge signal (i.e., npch signal) 825 that is output from the second logic gate and transmitted to transistor 640.

At 720, the precharge signal 825 is applied to the control gate 640a of transistor 640.

At 725, in an embodiment where transistor 640 is a p-channel transistor, when the precharge signal 825 is low during a first portion 850 of the signal, the precharge signal configures transistor 640 to turn on and to precharge (i.e., pull up) the read bitline.

At 730, a read word line signal (i.e., rwl(x)) 830 is applied to one of the read-access circuits 400 via the rwl line that is connected to the read-access circuit. The read word line signal turns on the transistor of the read-access circuit that is connected to the read bitline so that the memory cell connected to the read-access circuit may be sensed by the sense amp 655.

At 735, in an embodiment where transistor 640 is a p-channel transistor and when the precharge signal is high at second portion 855 of the signal, the precharge signal configures transistor 640 to turn off and to float (i.e., not pulled up and not pulled down) the read bitline. A float state is sometimes referred to as a tristate.

At 740, when the read bitline floats and read word line is enabled, the memory cell addressed by the address signal is sensed by the sense amp.

At 745, in an embodiment where transistor 640 is a p-channel transistor and after evaluation of the memory cell, when the precharge signal 825 is low at third portion 860 of the signal, the precharge signal configures transistor 640 to turn on to precharge the read bitline. In the high-speed mode of operation, the read bitline is precharged continuously except during evaluation of the memory cell. In an embodiment, the read bitline may be precharged for half of the read cycle or more in the high-speed mode.

In an alternative embodiment, where transistor 640 is an n-channel transistor, control circuit 600 configures the precharge signal as the complement of the precharge signal shown in FIG. 8. Thus, when the precharge signal is high, transistor 640 is turned on and the selected read bitline is precharged and when the precharge signal is low, transistor 640 is turned off the selected read bitline floats.

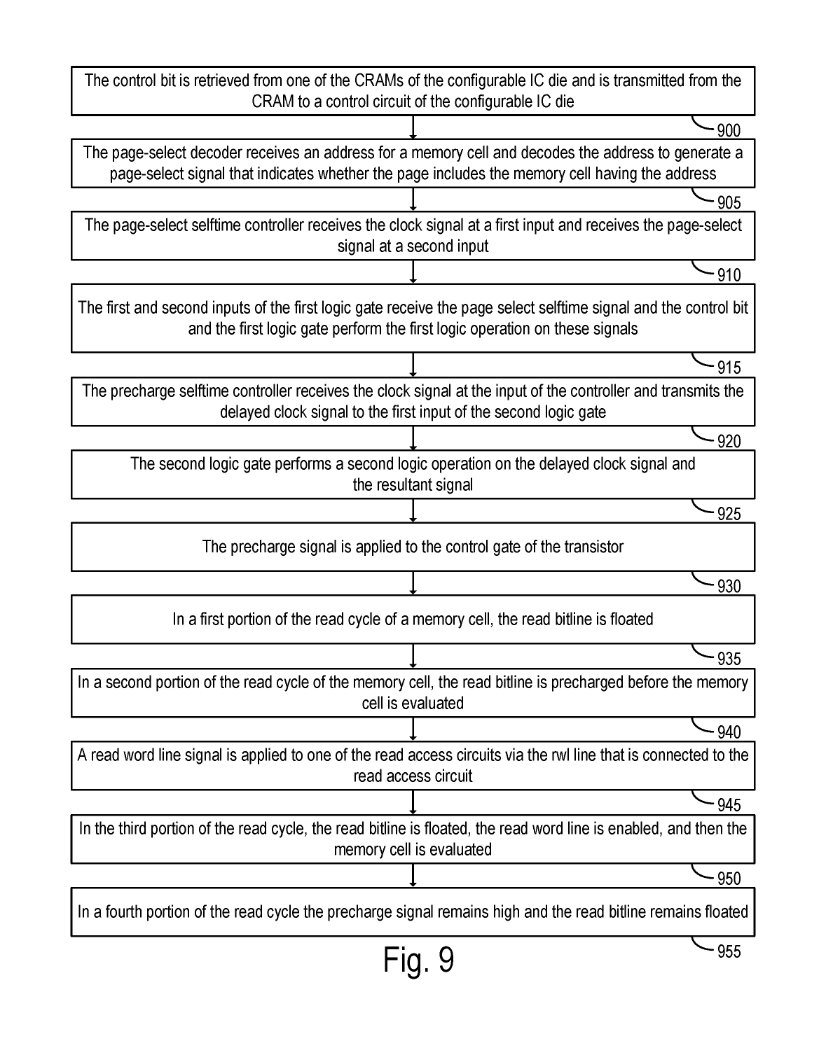

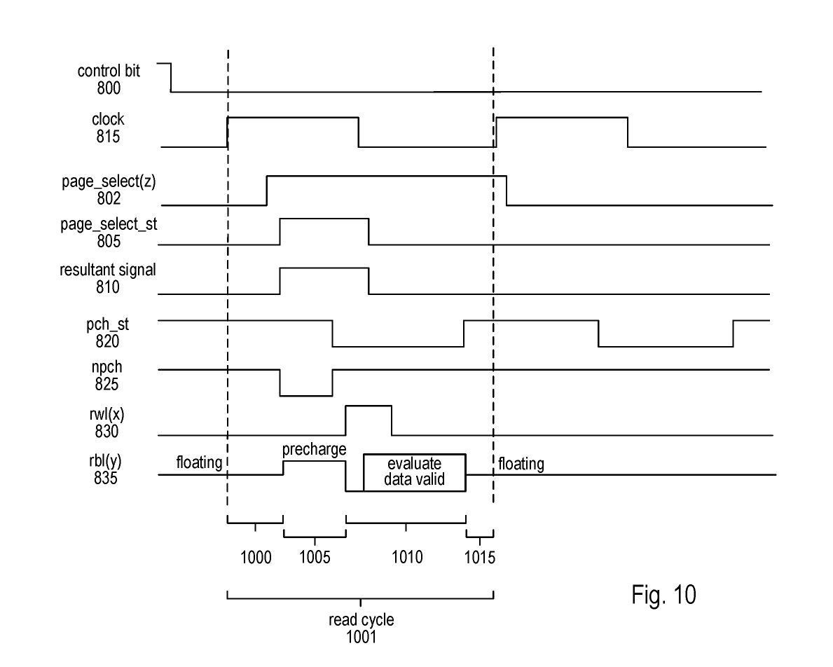

FIGS. 9 and 10 are a flow diagram of a method for a low-power mode of operation of a memory cell of a page of memory cells and a timing diagram for the low-power mode of operation during a read cycle of the memory cell. FIGS. 9 and 10 are described together. The flow diagram represents one example embodiment. Steps may be added to, removed from, or combined in the flow diagram without deviating from the scope of the embodiment.

The described method of operation is for one read bitline of one page of memory cells for low-power mode of operation where a memory cell connected to the read bitline is read during a read cycle. While the described method is for one read bitline, the method is applicable to all of the read bitlines of a page of memory cells where the page operates in the low-power mode of operation for memory cells that are read during a read cycle. For a page of memory cells that does not include memory cells that are read during the read cycle, the memory cells may be operated alternatively from the method of FIGS. 9 and 10. For example, the read lines for the memory cells may be tristated for the entirety of a read cycle.

At 900, a control bit 800 is retrieved from a CRAM 20 of configurable IC die 5 and is transmitted from the CRAM to the control circuit 600. Specifically, the control bit is transmitted to the second input 630b of the first logic gate 630.

For the low-power mode of operation, the control bit has the same state for all of the pages of memory cells of a memory device so that all of the pages of the memory device operate in a low-power mode of operation. In one embodiment, the control bit is low for all pages and in an alternative embodiment, the control bit is high for all pages. In the example embodiment described, the control bit is low for the low-power mode of operation.

At 905, the page-select decoder 615 receives an address for a memory cell and decodes the address to generate a page-select signal (i.e., page_select(z)) 802. The memory cell that has the address is read during the read cycle.

The page-select signal indicates whether a page includes a memory cell that has the address or does not have the address. A page (e.g., page 1) that includes the memory cell having the address is operated in the low-power mode of operation during the read cycle. That is all control circuits 600 and all read bitlines of the page are operated according to the described method of FIGS. 9 and 10.

In overview, in the low-power mode of operation, all of the read bitlines of the page (e.g., page 1) are precharged prior to evaluation of memory cells and are otherwise floated. Pages (e.g., page 0 and pages 2-7) that do not include a memory cell having the address are continuously floated. These operations are described further below.

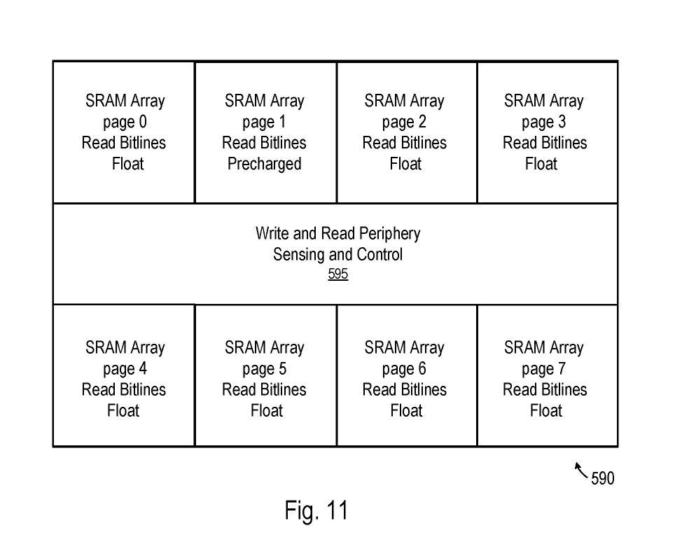

FIG. 11 shows the memory device 590 where one page (e.g., page 1) is operated in the described low-power mode of operation. All of the other pages (e.g., page 0 and pages 2-7) of the memory device have read bitlines that are floated during a read cycle of one or more memory cells of page 1.

At 910, the page-select selftime controller 620 receives the clock signal 815 at input 620a and receives the page-select signal 802 at input 620b. The page-select selftime controller generates the page-select selftime signal 805 based on the clock signal and the page-select signal 802.

At 915, the first input 630a of the first logic gate 630 receives the page-select selftime signal 805 and the second input 630b of the first logic gate 630 receives the control bit 800 from the CRAM 20. The first logic gate performs the first logic operation (e.g., an OR operation) on the page-select selftime signal 805 and the control bit 800 to generate the resultant signal 810. Because the control bit from the CRAM is low for the low-power mode of operation, the low control bit allows for the page-select selftime signal 805 to pass through the OR gate to control the state of the resultant signal 810. More generally, the control bit controls whether memory pages operate in a high-speed mode or a lower-power operation mode.

At 920, the precharge selftime controller 625 receives the clock signal 815 at the input 625a of the controller. The controller delays the clock signal and transmits the delayed clock signal 820 to the first input 635a of the second logic gate. Delayed clock signal 820 is sometimes referred to as the precharge selftime signal (i.e., pch_st).

At 925, the second logic gate 635 (e.g., a NAND gate) performs a second logic operation (e.g., a NAND operation) on the delayed clock signal 810 and the resultant signal 810 that is received from the first logic gate. The result signal of the second logic operation is the precharge signal (i.e., npch signal) 825 that is output from the second logic gate and transmitted to the transistor 640.

At 930, the precharge signal 825 is applied to the control gate 640a of transistor 640. In an embodiment where transistor 640 is a p-channel transistor, when the precharge signal 825 is low the precharge signal configures transistor 640 to turn on and to precharge (i.e., pull up) the read bitline and when the precharge signal 825 is high the precharge signal configures transistor 640 to turn off the transistor and the read bitline floats. In the low-power mode of operation, the default state (when the memory cell is not being evaluated) of the read bitline is floating as compared to the high-power mode of operation where the default state (when the memory cells is not being evaluated) of the read bitline is precharged.

At 935, in a first portion 900 of the read cycle 1001 of a memory cell when the precharge signal 825 high, transistor 640 is off and the read bitline floats.

At 940, in a second portion 905 of the read cycle 1001 of the memory cell when the precharge signal 825 is low, the read bitline is precharged before the memory cell is evaluated at a third portion 910 of the read cycle.

At 945, a read word line signal (i.e., rwl(x)) 830 is applied to one of the read-access circuits 400 via the rwl line that is connected to the read-access circuit. The read word line signal turns on the transistor of the read-access circuit that is connected to the read bitline so that the memory cell connected to the read-access circuit may be read by the sense amp 655.

At 950, in the third portion 910 of the read cycle 1001, the precharge signal 825 is high, the read bitline floats, and then the memory cell is evaluated.

At 955, in a fourth portion 915 of the read cycle 1001, the precharge signal 825 remains high and the read bitline remains floating. In the low-power mode of operation, the read bitline floats longer than in the high-power mode of operation.

In an alternative embodiment, where transistor 640 is an n-channel transistor, control circuit 600 configures the precharge signal is the complement of the precharge signal shown in FIG. 9. Thus, when the precharge signal is high, transistor 640 is turned on and the selected read bitline is precharged and when the precharge signal is low, transistor 640 is turned off the selected read bitline floats.

In an embodiment, a first set of memories (e.g., a first set of SRAMs) of the configurable IC die are configured and operated according to FIGS. 7 and 8 in the high-power mode of operation, and a second set of memories (e.g., a second set of SRAMs) of the configurable IC die are configured and operated according to FIGS. 9 and 10 in the low-power mode of operation. A set of memories may include one or more memories. One or more CRAMs of the configurable IC die may be configured to provide control bits that facilitate the operation of the first set of memories in the high-power mode of operation. The one or more CRAMs may be configured to provide control bits that facilitate the operation of the second set of memories in the low-power mode of operation. The first set of memories may include one or more memories and the second set of memories may include one or more memories.

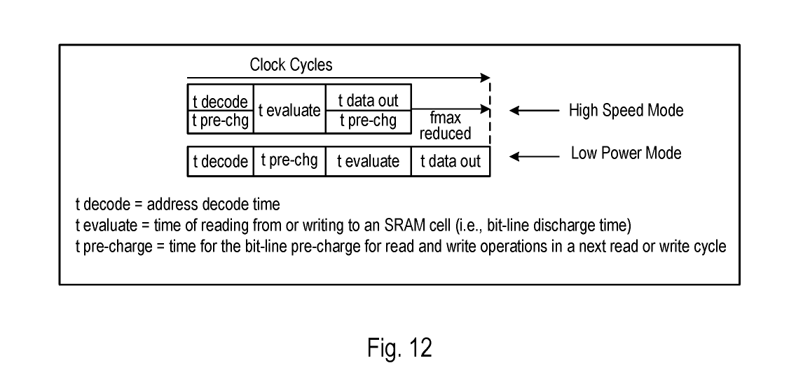

FIG. 12 shows a diagram of a high-speed read cycle and a low-power read cycle. The high-speed read cycle is shorter than the low-power read cycle. In the high-speed mode of operation, a signal read from a memory cell may be decoded and a read bitline may be precharged in the same portion of a clock cycle or in the same clock cycle. Additionally, in the high-speed mode of operation, a signal may be read from a memory cell and a read bitline may be precharged in the same portion of a clock cycle or in the same clock cycle. In contrast, in the low-power mode of operation, a signal read from a memory cell may be decoded and a read bitline may not occur in the same portion of a clock cycle or in the same clock cycle. Additionally, in the low-power mode of operation, a signal may be read from a memory cell and a read bitline may be precharged may not occur in the same portion of a clock cycle or in the same clock cycle.

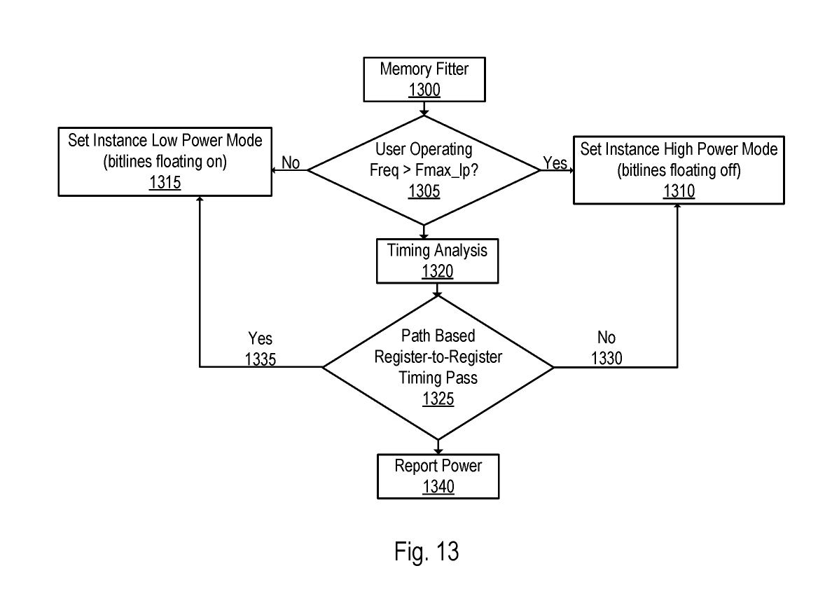

FIG. 13 is a flow diagram for determining whether a page of memory cells of a memory should be configured for a low-power mode of operation or a high-speed mode of operation based on the timing performance of a read cycle. The flow diagram represents one example embodiment. Steps may be added to, removed from, or combined in the flow diagram without deviating from the scope of the embodiment. The blocks in the flow diagram may represent blocks of computer code operable on a computer system and stored on a computer readable medium of the computer system or stored on another computer readable medium.

At 1300, the configurable IC die compilation software (e.g., Quartus™) may map and fit a circuit into the core fabric of a configurable IC die.

At 1305, the software may configure each memory (e.g., each SRAM) for a low-power mode of operation or a high-speed mode of operation. Specifically, the software may set a bit in the CRAM for each memory so that the memory will operate in the low-power mode of operation or the high-speed mode of operation. If a user intends to operate a particular memory at a frequency that is greater than the maximum frequency for the low-power mode of operation, then the software may configure the CRAM so that the particular memory will operate in the high-speed mode of operation (1310). If a user intends to operate the memory at a frequency that is less than or equal to the maximum frequency for the low-power mode of operation, then the software may configure the CRAM so that the particular memory will operate in the low-power mode of operation (1315).

At 1320, the software may run a simulation of the configurable IC die, the circuit being mapped and fitted into the configurable IC die, and the memories. During the simulation, the software may perform a timing analysis of the memories. The software may simulate the memories configured for the low-power mode of operation. If a given one of the memories that is configured for the low-power mode of operation operates too slowly for adequate performance of the circuit, then the software may reconfigure the given memory to operate in the high-speed mode of operation (1325). Specifically, the software may reconfigure the CRAM so that the particular memory will operate in the high-speed mode of operation.

Alternatively, if the given one of the memories that is configured for the low-power mode of operation operates adequately for the circuit, then the software may not reconfigure the given memory to operate in the high-speed mode of operation, but may leave the given memory in the low-power mode of operation (1330). Specifically, the software may not reconfigure the CRAM so that the particular memory will operate in the high-speed mode of operation, but leave the CRAM unchanged to the memory is configured for the low-power mode of operation.

At 1335, subsequent to operating the simulation of the memories, the software may report the power consumption of for the configurable IC die, the memories, or both.

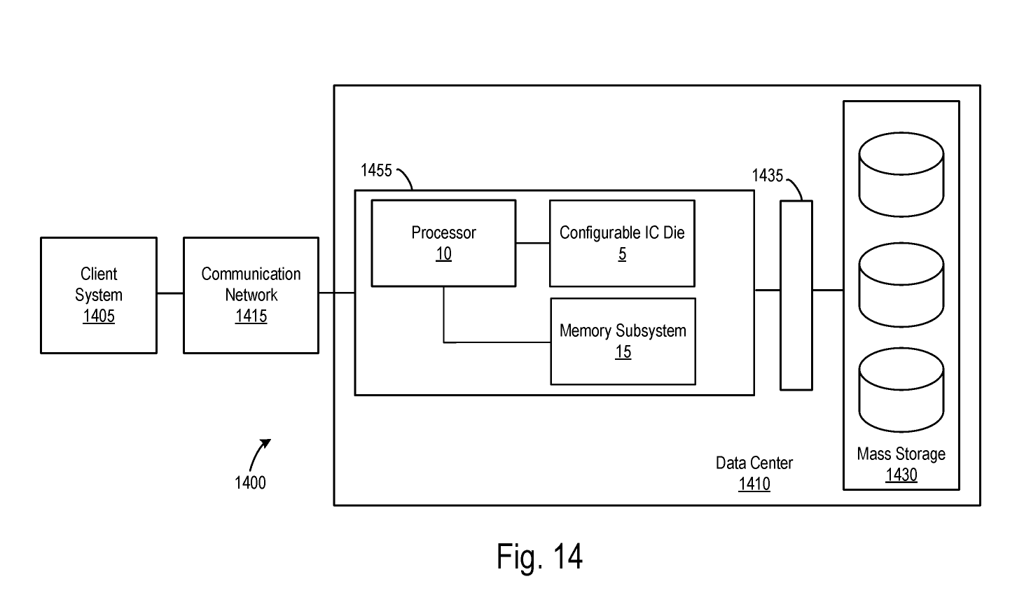

FIG. 14 illustrates a data system 1400, in an embodiment. Data system 1400 includes a client system 1405 that is adapted to access a data center 1410 using a communication network 1415. The client system 1405 may include one or more client computers that are adapted to access data stored in the data center. The client computer may include a server, a desktop computer, a laptop computer, a mobile device (e.g., a tablet computer, a smartphone, or other devices), any combination of these devices, or other devices. The client computer may transfer data to the data center for storage in the data center, retrieve data from the data center, or request the alteration of data in the data center. Communication network 1415 may include one or more networks, such as the Internet, one or more intranets, or other network systems.

Data center 1410 includes a host 1455 (i.e., server), mass storage 1430, an IP switch 1435, and may include other elements. Host 1455 in the data center may include one or more processors 10, any of the configurable IC dies 5 described above and shown in the figures, a memory subsystem 15, and other server elements. The configurable IC die 5 in the data center may operate according to any of the methods described and illustrated, such as the methods illustrated in FIGS. 7-10.

Mass storage 1430 includes one or more types of memory devices, such as a disk array that includes several disk memory devices (e.g., magnetic disk memory), optical storage (e.g., optical disk storage), solid-state memory, tape memory, and others. The memory devices may be located in one or more data center racks, which include one or more of the servers, the IP switch, both, or do not include the servers and the IP switch. The IP switch routes communication packets between the servers and the memory devices of the mass storage.

The one or more processing cores 10 of the server may communicate with the memory subsystem at a single data rate (SDR), double data rate (DDR), or quad data rate (QDR) in half or full duplex mode. The memory subsystem may include DDR non-volatile memory, 3D xPoint non-volatile memory, or other types of memory.

The server may be an aggregated server or a disaggregated server. Various component of the server may be located on a single sled in a data center rack, are distributed among two or more sleds in a data center rack, or are distributed among a number of sleds in a number of data center racks. Distributing components of a server among sleds, data center racks, or both may facilitate relatively fast communication between the components by positioning select components in frequent communication relatively close to each other. For example, in a server where the processor accesses the memory subsystem more frequently than the configurable IC die (e.g., FPGA), the processor and memory subsystem may be located relatively close (e.g., on a first sled) in a data center rack and the configurable IC die may be located farther from the memory subsystem (e.g., on a different second sled) in the data center rack. Alternatively, the second sled may be positioned nearer the mass storage than the first sled, for example, if the configurable IC die accesses the mass storage with a higher frequency than the processor.

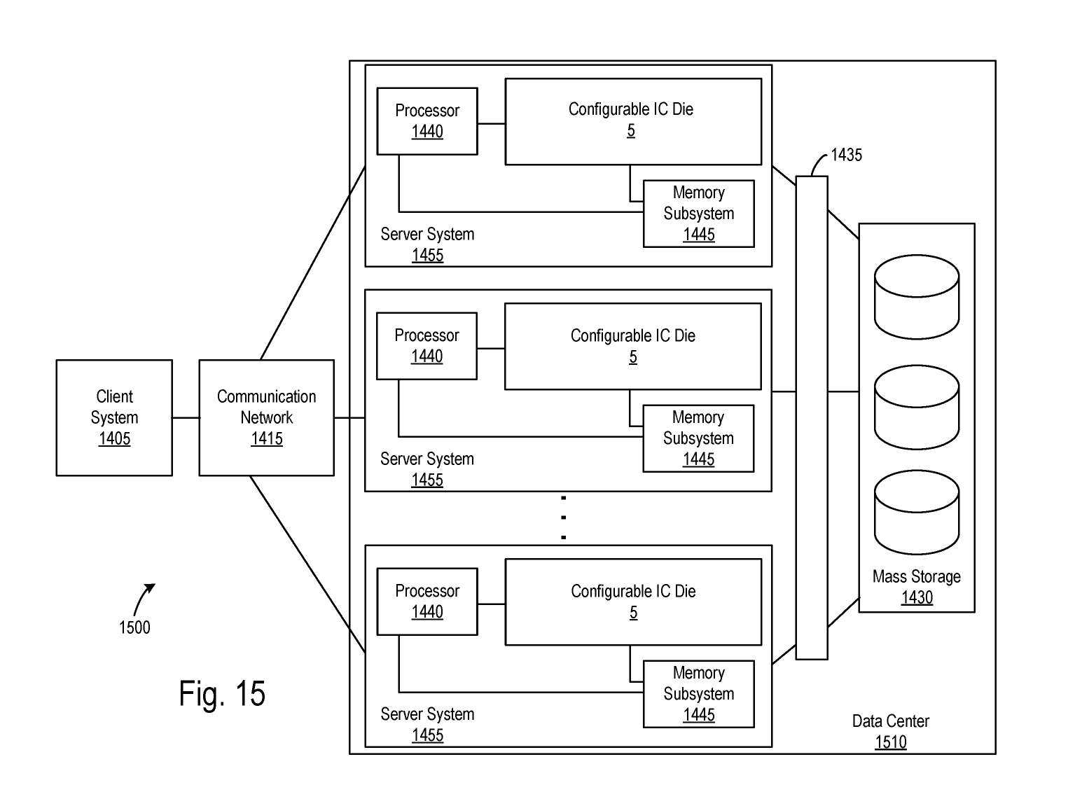

FIG. 15 illustrates a data system 1500, in an embodiment. Data system 1500 is similar to data center 1400, but includes a data center 1510 that includes a number of hosts 1455 (i.e., servers). Further, each of the hosts in the data center may include any of the configurable IC dies 5 described above and shown in the figures.

In an embodiment, a method includes receiving at a page-select decoder an address for a memory cell of a first page that is included in a plurality of pages of a memory device. A configurable IC die includes the memory device. The method includes decoding, by the page-select decoder, the address, and generating, by the page-select decoder, a page-select signal based on decoding the address. The page-select signal indicates that the first page includes the memory cell.

The method includes receiving, at a page-select selftime controller, a clock signal and the page-select signal, and generating, by the page-select selftime controller, a page-select selftime signal based on the clock signal and the page-select signal. The method includes performing, by a first logic gate, a first logic function on the page-select selftime signal and the page-select signal.

The method includes generating a precharge signal based on performing the first logic function. The method includes receiving the precharge signal at a control transistor that is coupled to a read bitline of the first page.

The method includes during a read cycle of the memory cell based on the precharge signal: tristating the read bitline during a first portion of the precharge signal, thereafter precharging the read bitline during a second portion of the precharge signal for an evaluation of the memory cell, and thereafter, tristating the read bitline during a third portion of the precharge signal.

In an embodiment, the method further includes tristating read bitlines of pages of the plurality of pages, not including the first page, during the first, second, and third portions of the precharge signal. The pages of the plurality of pages, not including the first page, are pages of the memory device. The pages of the plurality of pages, not including the first page, do not include memory cells having the address.

In an embodiment, the method further includes evaluating the memory cell during the second portion of the precharge signal. The second portion of the precharge signal is temporally after the first portion of the precharge signal and the third portion of the precharge signal is temporally after the first and second portions of the precharge signal.

In an embodiment, the method further includes receiving the page-select selftime signal at a second logic gate; receiving a control bit from a configurable random access memory (CRAM) of the configurable IC die at a second logic gate; performing a second logic function on the page-select selftime signal and the control bit; and transmitting the page-select selftime signal from the second logic gate to the first logic gate, based on the second logic function being performed on the page-select selftime signal and control bit.

In an embodiment, the method includes setting a plurality of control bits, that includes the first-mentioned control bit, in the CRAM when a circuit is mapped and fitted to the configurable IC die. The second logic gate may be an OR gate. The first logic gate may be a NAND gate.

In an embodiment, a configurable IC die includes a memory device that includes a plurality of pages. Each page includes a plurality of memory cells, plurality of read-access circuits coupled to the plurality of memory cells, a plurality of precharge transistors, and a plurality of read bitlines. Each read bitline is coupled between one of the precharge transistors and one of the read-access circuits.

The configurable IC die includes a plurality of control circuits coupled to the plurality of read-access circuits. Each control circuit includes a page-select decoder, a page-select selftime controller, a precharged selftime controller, a first logic gate, and a second logic gate. The configurable IC die includes a configurable random access memory (CRAM) coupled to each control circuit. Each precharge selftime controller is coupled between a clock supply line and a first input of one of the second logic gates. Each page select decoder is coupled between an address supply line and one of the page-select selftime controllers. Each page-select selftime controller is coupled between the clock supply line and a first input of one the first logic gates and between one of the page select decoders and the first input of the one of the first logic gates. The CRAM is coupled to a second input of the one of the first logic gates. An output of the one of the first logic gates is coupled to a second input of the one of the second logic gates, and an output of the one of the second logic gates is coupled to one of the precharge transistors.

An input of the precharge selftime controller may be coupled the clock supply line, a first input of the page-select selftime controller may be coupled to the clock supply line, and the input of the precharge selftime controller may be coupled to the first input of the page-select selftime controller. Each of the first logic gates may be an OR gate. Each of the second logic gates may be a NAND gate. Each precharge transistor may be coupled between a power supply line and one of the read bitlines to pull up the read bitline under control of the control circuit or tristate the read bitline under control of the control circuit. Each bit transmitted from the CRAM to each of the first logic gates may configure operation of each page of memory cells to operate in a high-power mode of operation or a low-power mode of operation, and power consumption in the high-power mode of operation is greater than in the low-power mode of operation of each page of memory cells.

In an embodiment, a method includes when an operating frequency of a first memory of the configurable IC die is above a threshold operating frequency for a low-power mode of operation of the first memory, setting a first plurality of bits of a configurable random access memory (CRAM) of the configurable IC die for configuring pages of the first memory for a high-power mode operation.

The method includes when an operating frequency of a second memory of the configurable IC die is less than or equal to the threshold operating frequency, setting a second plurality of bits of the CRAM for configuring pages of the second memory for a low-power mode operation. Power consumption of the high-power mode of operation of the first memory is greater than power consumption of the low-power mode of operation of the second memory.

The method includes performing a simulated operation of the second memory, and when an operation time of the second memory is determined to be slower than a threshold based on the simulated operation, setting the second plurality of bits of the CRAM for configuring pages of the second memory for the high-power mode operation.

In an embodiment, the method further includes when an operation time of the second memory is determined to be at or higher than the threshold based on the simulated operation, not changing the second plurality of bits of the CRAM for configuring pages of the second memory for the high-power mode operation. A plurality of first logic gates of the second memory use the second plurality of bits to set the pages for the second memory for the high power mode of operation or the low-power mode of operation. During operation in the high-power mode of operation, read bitlines of the pages of the second memory are precharged for a first period of time and tristated for a second period of time, during operation in the low-power mode of operation, the read bitlines of the pages of the second memory are precharged for a third period of time and tristated for a fourth period of time, the first period of time is greater than the third period of time, and the second period of time is less than the fourth period of time.

This description has been presented for the purposes of illustration and description. It is not intended to be exhaustive or to limit the invention to the precise form described, and many modifications and variations are possible considering the teaching above. For example, while SiP devices have been described above, embodiments described may be applied to a variety of multi-chip modules, multi-die assemblies, system-on-package devices, and other multi-die devices. The implementations were chosen and described in order to best explain the principles of the embodiments and their practical applications. This description will enable others skilled in the art to best utilize and practice the invention in various implementations and with various modifications as are suited to a particular use. The scope of the invention is defined by the following claims.

1. A method comprising:
receiving at a page-select decoder an address for a memory cell of a first page that is included in a plurality of pages of a memory device, wherein a configurable IC die includes the memory device;
decoding, by the page-select decoder, the address;
generating, by the page-select decoder, a page-select signal based on decoding the address, wherein the page-select signal indicates that the first page includes the memory cell;
receiving, at a page-select selftime controller, a clock signal and the page-select signal;
generating, by the page-select selftime controller, a page-select selftime signal based on the clock signal and the page-select signal;
performing, by a first logic gate, a first logic function on the page-select selftime signal and the page-select signal;
generating a precharge signal based on performing the first logic function;
receiving the precharge signal at a control transistor that is coupled to a read bitline of the first page; and
during a read cycle of the memory cell based on the precharge signal: tristating the read bitline during a first portion of the precharge signal, thereafter precharging the read bitline during a second portion of the precharge signal for an evaluation of the memory cell, and thereafter, tristating the read bitline during a third portion of the precharge signal.

2. The method of claim 1, further comprising tristating read bitlines of pages of the plurality of pages, not including the first page, during the first, second, and third portions of the precharge signal.

3. The method of claim 2, wherein the pages of the plurality of pages, not including the first page, are pages of the memory device.

4. The method of claim 3, wherein the pages of the plurality of pages, not including the first page, do not include memory cells having the address.

5. The method of claim 1, further comprising evaluating the memory cell during the second portion of the precharge signal.

6. The method of claim 1, wherein the second portion of the precharge signal is temporally after the first portion of the precharge signal and the third portion of the precharge signal is temporally after the first and second portions of the precharge signal.

7. The method of claim 1, further comprising:
receiving the page-select selftime signal at a second logic gate;
receiving a control bit from a configurable random access memory (CRAM) of the configurable IC die at a second logic gate;
performing a second logic function on the page-select selftime signal and the control bit; and
transmitting the page-select selftime signal from the second logic gate to the first logic gate, based on the second logic function being performed on the page-select selftime signal and control bit.

8. The method of claim 7, wherein the second logic gate is an OR gate.

9. The method of claim 8, wherein the first logic gate is a NAND gate.

10. The method of claim 8, comprising setting a plurality of control bits, that includes the first-mentioned control bit, in the CRAM when a circuit is mapped and fitted to the configurable IC die.

11. A configurable IC die comprising:
a memory device comprising a plurality of pages, wherein each page comprises a plurality of memory cells, plurality of read-access circuits coupled to the plurality of memory cells, a plurality of precharge transistors, and a plurality of read bitlines, each read bitline is coupled between one of the precharge transistors and one of the read-access circuits;
a plurality of control circuits coupled to the plurality of read-access circuits, wherein each control circuit comprises a page-select decoder, a page-select selftime controller, a precharged selftime controller, a first logic gate, and a second logic gate;
a configurable random access memory (CRAM) coupled to each control circuit, wherein
each precharge selftime controller is coupled between a clock supply line and a first input of one of the second logic gates,
each page select decoder is coupled between an address supply line and one of the page-select selftime controllers,
each page-select selftime controller is coupled between the clock supply line and a first input of one the first logic gates and between one of the page select decoders and the first input of the one of the first logic gates,
the CRAM is coupled to a second input of the one of the first logic gates,
an output of the one of the first logic gates is coupled to a second input of the one of the second logic gates, and an output of the one of the second logic gates is coupled to one of the precharge transistors.

12. The configurable IC die of claim 11, wherein an input of the precharge selftime controller is coupled the clock supply line, a first input of the page-select selftime controller is coupled to the clock supply line, and the input of the precharge selftime controller is coupled to the first input of the page-select selftime controller.

13. The configurable IC die of claim 11, wherein each of the first logic gates is an OR gate.

14. The configurable IC die of claim 13, wherein each of the second logic gates is a NAND gate.

15. The configurable IC die of claim 11, wherein each precharge transistor is coupled between a power supply line and one of the read bitlines to pull up the read bitline under control of the control circuit or tristate the read bitline under control of the control circuit.

16. The configurable IC die of claim 11, wherein each bit transmitted from the CRAM to each of the first logic gates configures operation of each page of memory cells to operate in a high-power mode of operation or a low-power mode of operation, and power consumption in the high-power mode of operation is greater than in the low-power mode of operation of each page of memory cells.

17. A method comprising:
when an operating frequency of a first memory of the configurable IC die is above a threshold operating frequency for a low-power mode of operation of the first memory, setting a first plurality of bits of a configurable random access memory (CRAM) of the configurable IC die for configuring pages of the first memory for a high-power mode operation;
when an operating frequency of a second memory of the configurable IC die is less than or equal to the threshold operating frequency, setting a second plurality of bits of the CRAM for configuring pages of the second memory for a low-power mode operation, wherein power consumption of the high-power mode of operation of the first memory is greater than power consumption of the low-power mode of operation of the second memory;
performing a simulated operation of the second memory; and
when an operation time of the second memory is determined to be slower than a threshold based on the simulated operation, setting the second plurality of bits of the CRAM for configuring pages of the second memory for the high-power mode operation.

18. The method of claim 17, further comprising when an operation time of the second memory is determined to be at or higher than the threshold based on the simulated operation, not changing the second plurality of bits of the CRAM for configuring pages of the second memory for the high-power mode operation.

19. The method of claim 17 wherein a plurality of first logic gates of the second memory use the second plurality of bits to set the pages for the second memory for the high power mode of operation or the low-power mode of operation.

20. The method of claim 19 wherein during operation in the high-power mode of operation, read bitlines of the pages of the second memory are precharged for a first period of time and tristated for a second period of time,
during operation in the low-power mode of operation, the read bitlines of the pages of the second memory are precharged for a third period of time and tristated for a fourth period of time,
the first period of time is greater than the third period of time, and
the second period of time is less than the fourth period of time.
